(19) United States
(12) Patent Application Publication
(10) Pub. No.: US 2015/0101536 A1
(43) Pub. Date: Apr. 16, 2015

(54) MASK ASSEMBLY AND DEPOSITION APPARATUS USING THE SAME FOR FLAT PANEL DISPLAY

(71) Applicant: SAMSUNG DISPLAY CO., LTD., Yongin-City (KR)

(72) Inventor: Jeong Won HAN, Chungcheongnam-do (KR)

(21) Appl. No.: 14/446,665

(22) Filed: Jul. 30, 2014

(30) Foreign Application Priority Data
Oct. 11, 2013 (KR) 10-2013-0121462

(51) Int. Cl. C23C 16/04; C23C 16/44

(52) U.S. Cl. CPC C23C 16/042; C23C 16/44
USPC 118/721; 118/505

(57) ABSTRACT

A mask assembly includes a mask frame including an opening and a frame enclosing the opening, a pattern mask including a pattern part in which at least one pattern is disposed thereon and a coupling part coupled to the frame, a supporter crossing the opening and coupled to the pattern mask, and a fixing pin coupling the pattern mask and the supporter to each other. At least one of the pattern mask and the supporter has a fixing part including a plurality of holes, and the fixing pin is disposed in the fixing part and at least one end of the fixing pin has a “T” shape to fix the pattern mask and the supporter to each other.

### CROSS-REFERENCE TO RELATED APPLICATION

This application claims priority to Korean Patent Application No. 10-2013-0121462 filed on Oct. 11, 2013, the disclosure of which is hereby incorporated herein by reference herein in its entirety.

### (a) TECHNICAL FIELD

The present disclosure relates to a mask assembly and a deposition apparatus using the same for a flat panel display.

### (b) DISCUSSION OF THE RELATED ART

Flat panel displays have replaced cathode ray tube displays due to their characteristics including light weight and small size. Typical examples of flat panel displays include a liquid crystal display (LCD) and an organic light emitting diode (OLED) display. In those displays, the organic light emitting diode display have excellent luminescence and viewing angle characteristics, as compared with the liquid crystal display (LCD), and do not need a backlight, such that they can be implemented in very small sizes.

For example, the organic light emitting diode (OLED) display adopts a photolithography method or a deposition method using a deposition mask assembly in which a pattern including a plurality of slits is formed to selectively form the cathode, the anode, the organic thin film, and the like on a substrate formed of glass, stainless steel, or synthetic resin. In the photolithography method, after a photoresist is applied on some regions, moisture may inflow in the course of stripping and etching the photoresist by a wet etching or dry etching method. Accordingly, the deposition method using the deposition mask assembly is used with a material that may deteriorate by moisture like the organic thin film.

The organic light emitting diode (OLED) display includes an organic light emitting diode (OLED) including R, G, and B organic emission layers to display full colors, and for this, patterns of the R, G, and B organic emission layers are formed on a substrate by aligning a mask pattern in which a plurality of openings are formed on the substrate on which the organic light emitting diode (OLED) including a deposition object are to be provided. That is, the R, G, and B organic emission layers, will be formed and the deposition object of the R, G, and B organic emission layers will be provided through the openings of the mask pattern to deposit patterns of a desired shape on the substrate, thereby forming the organic light emitting diode (OLED) including the R, G, and B organic emission layers at a predetermined region on the substrate. Accordingly, the pattern of the mask assembly must be very precisely aligned.

### SUMMARY

Exemplary embodiments of the present invention provide a mask assembly removing a heat influence due to welding between a mask and a supporter and a change thereby, and removing or minimizing a protrusion on the supporter and a deposition apparatus using the same for a flat panel display.

A mask assembly according to an exemplary embodiment of the present invention includes a mask frame including an opening and a frame enclosing the opening, a pattern mask including a pattern part in which at least one pattern is disposed thereon and a coupling part coupled to the frame, a supporter crossing the opening and coupled to the pattern mask, and a fixing pin coupling the pattern mask and the supporter to each other. At least one of the pattern mask and the supporter has a fixing part including a plurality of holes, and the fixing pin is disposed in the fixing part and at least one end of the fixing pin has a “T” shape to fix the pattern mask and the supporter to each other.

The pattern may include at least one slit.

The pattern mask may be made of at least one unit pattern mask.

The supporter may be formed in plural and separated from each other.

The supporter may be disposed in a length direction of the pattern mask.

The supporter may be disposed in a direction perpendicular to the length direction of the pattern mask.

The supporter may be disposed in both the direction of the length direction of the pattern mask and the direction perpendicular to the length direction.

The frame may have a groove configured to receive an end of the supporter therein.

At least one of the pattern mask and the supporter may have a receiving groove configured to receive the “T” shaped end of the fixing pin therein.

The fixing pin may be formed of a metal or a plastic material.

The fixing pin may be formed of a material that is etched by an etchant.

The fixing pin may be coupled to the pattern mask or the supporter.

The fixing pin may be united with one of the pattern mask or the supporter.

A deposition apparatus for a flat panel display according to an exemplary embodiment of the present invention includes a chamber, a deposition source disposed at a lower side of the chamber and a mask assembly disposed on the deposition source and configured to support a substrate. The mask assembly includes a mask frame including an opening and a frame enclosing the opening, a pattern mask including a pattern part in which at least one pattern is disposed thereon and a coupling part coupled to the frame, a supporter crossing the opening and coupled to the pattern mask, and a fixing pin coupling the pattern mask and the supporter to each other. At least one of the pattern mask and the supporter has a fixing part including a plurality of holes, and the fixing pin is disposed in the fixing part and at least one end of the fixing pin has a “T” shape to fix the pattern mask and the supporter to each other.

In accordance with an exemplary embodiment of the present invention, a mask assembly is provided. The mask frame assembly includes a mask frame including an opening and a frame enclosing the opening, a plurality of pattern masks including a pattern part in which a plurality of patterns are disposed thereon and a coupling part coupled to the frame, a plurality of supporters crossing the opening of the mask frame underneath the pattern masks and supporting the pattern masks thereon, and a plurality of fixing pins coupling the pattern masks and the supporters to each other.

The pattern masks and/or the supporters have a fixing part including a plurality of holes, and the fixing pins are disposed in a corresponding one of the fixing parts and at least one end of the fixing pins have a “T” shape to fix the pattern masks and the supporters to each other. The supporters are fixed to the pattern masks at gaps between the patterns. In addition, the supporters have a width which is narrower than a width of the gaps between the patterns of the pattern masks such that the supporters do not shield the patterns of the pattern masks when the supporters and the pattern masks are fixed to each other.

As described above, according to an exemplary embodiment of the present invention, compared with a method of fixing the supporter and the mask by welding or by forming a protrusion at one side, the deformation of the mask and the supporter by the thermal influence may be removed, the height of the protrusion may be controlled, and the fixing force of the supporter and the mask may be strong such that a mask assembly controlling a shadow phenomenon may be provided.

### BRIEF DESCRIPTION OF THE DRAWINGS

Exemplary embodiments of the present invention can be understood in more detail from the following detailed description taken in conjunction with the attached drawings in which:

FIG. 1 is a perspective view of a mask assembly according to an exemplary embodiment of the present invention.

FIG. 2 is an enlarged perspective view of a pattern of a mask according to an exemplary embodiment of the present invention.

FIG. 3 is a perspective view of a mask assembly according to an exemplary embodiment of the present invention.

FIG. 4 is a top plan view of a mask assembly according to an exemplary embodiment of the present invention.

FIG. 5 is a perspective view of a mask assembly according to an exemplary embodiment of the present invention.

FIG. 6 is a perspective view of a mask assembly according to an exemplary embodiment of the present invention.

FIG. 7 is a perspective view of a mask assembly according to an exemplary embodiment of the present invention.

FIG. 8 is a perspective view of a mask assembly according to an exemplary embodiment of the present invention.

FIG. 9 is a diagram showing a manufacturing process of a mask assembly according to an exemplary embodiment of the present invention.

FIG. 10 and FIG. 11 are diagrams showing a manufacturing process of a mask assembly according to an exemplary embodiment of the present invention.

FIG. 12 and FIG. 13 are diagrams showing a manufacturing process of a mask assembly according to an exemplary embodiment of the present invention.

FIG. 14 is a diagram showing a manufacturing process of a mask assembly according to an exemplary embodiment of the present invention.

FIG. 15 is a schematic diagram of deposition equipment for a flat panel display using a mask assembly according to an exemplary embodiment of the present invention.

### DETAILED DESCRIPTION OF EXEMPLARY EMBODIMENTS

Exemplary embodiments of the present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., may be exaggerated for clarity. Like reference numerals designate like elements throughout the specification. It will be understood that when an element such as a layer, film, region, or substrate is referred to as being “on” another element, it can be directly on the other element or intervening elements may also be present.

As used herein, the singular forms, “a”, “an”, and “the” are intended to include plural forms as well, unless the context clearly indicates otherwise.

Now, a mask assembly according to an exemplary embodiment of the present invention will be described with reference to accompanying drawings.

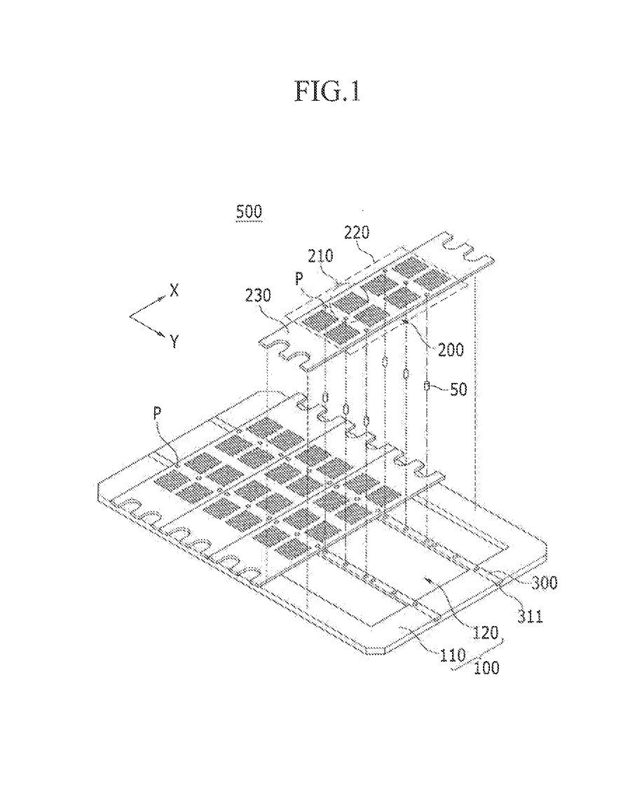

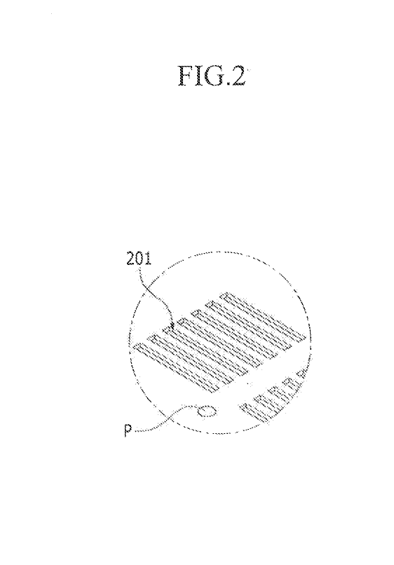

Firstly, the mask assembly according to an exemplary embodiment of the present invention will be described with reference to FIG. 1 and FIG. 2.

FIG. 1 is a perspective view of a mask assembly according to an exemplary embodiment of the present invention. FIG. 2 is an enlarged perspective view of a pattern of a mask according to an exemplary embodiment of the present invention.

Referring to FIG. 1 and FIG. 2, the mask assembly 500 according to an exemplary embodiment of the present invention includes, for example, a mask frame 100 having an opening 120, a plurality of pattern masks 200 extended in a first direction X of a length direction to be coupled to the mask frame 100, a supporter 300 crossing the opening 120, and a fixing pin 50 fixing the pattern mask 200 and the supporter 300. In an exemplary embodiment of the present invention, a plurality of pattern masks 200 are, for example, extended and coupled to the mask frame 100 in the first direction X. However, a single pattern mask 200 having an area corresponding to the opening 120 may be extended, for example, in one direction among the first direction X and a second direction Y perpendicular to the first direction X, or in all directions.

The mask frame 100 includes, for example, the opening 120 and a frame 110 enclosing the opening 120 and coupled to the pattern mask 200. In addition, the frame 110 of the mask frame 100 is formed of a material having a small change against a compressive force, such as, for example, a metal material having high rigidity, so that an end of the pattern mask 200 may be coupled and fixed thereto.

The pattern mask 200 includes, for example, a pattern part 220 in which one or a plurality of patterns 210 are formed to correspond to the opening 120, and a coupling part 230 extended in the first direction X and coupled to the frame 110, and the pattern 210 includes one or a plurality of slits 201. Here, the pattern mask 200 may be a fine metal mask formed of a metal thin film. For example, the pattern mask 200 may be formed of, for example, one selected from a group including a steel use stainless (SUS), invar, nickel, cobalt, and alloys thereof.

The supporter 300 is positioned to cross the opening 120 of the mask frame 100 to prevent the pattern mask 200 from being deformed, as shown in FIG. 1. For example, in an embodiment, when a plurality of pattern masks 200 are coupled to the mask frame 100, the supporter 300 may cross the opening 120 in the second direction Y perpendicular to the first direction X as the length direction of the pattern mask 200. To prevent the pattern 210 of the pattern mask 200 from being shielded by the coupling between the supporter 300 and the pattern mask 200, the supporter 300 is coupled to the pattern mask 200 between the patterns 210 of the pattern mask 200, and thereby a coupling point P between the supporter 300 and the pattern mask 200 is positioned between the patterns 210.

The supporter 300 and the pattern mask 200 respectively have the fixing part P in which the fixing pin 50 is inserted between the patterns 210 of the pattern mask 200 to be fixed. Fixing parts P may be respectively formed in plural in the supporter 300 and the pattern mask 200, and the positions of the fixing parts P of the supporter 300 and the pattern mask 200 are mutually positioned to correspond to each other. In an exemplary embodiment of the present invention, three fixing parts P formed at the supporter 300 and the pattern mask 200 are arranged for each pattern mask 200 in the second direction Y, but exemplary embodiments are not limited thereto. Rather, in an exemplary embodiment, there may be less than or more than three fixing parts P.

The fixing pin 50 penetrates the corresponding fixing part P of the supporter 300 and the pattern mask 200 thereby having a function of mutually fixing the supporter 300 and the pattern mask 200. In this case, the fixing pin 50 may have, for example, a cylinder shape, but exemplary embodiments are not limited thereto. For example, in an exemplary embodiment, the fixing pin 50 may have various shapes such as a triangular column shape or a quadrangular column shape, corresponding to the shape of the fixing part P.

Protruded parts of both ends of the fixing pin 50 that are positioned under the supporter 300 and on the pattern mask 200 are pressed by a pressure such that the ends are spread and the pressed cross-section is transformed into, for example, a “T” shape, and thereby the supporter 300 and the pattern mask 200 are fixed to not be mutually separated.

An upper portion and a lower portion of the fixing pin 50 are pressed by the pressure such that both ends thereof are formed to have the spread T shape. A gap may be generated by a head height of the pressed and spread fixing pin 50 of the T shape when the pattern mask 200 contacts the substrate. Accordingly, a receiving groove (not shown) receiving the fixing pin 50 of the “T” shape that is formed by the pressed and spread fixing pin 50 may be formed at a circumference of the fixing part P on the pattern mask 200 and under the supporter 300.

Also, according to the process, the receiving groove of the “T” shape of the pressed and spread fixing pin 50 may not be formed. In this case, when performing a deposition process, as a distance between the substrate and the pattern mask 200 is controlled by using the fixing pin 50, a degree of a shadow effect may be artificially controlled.

Further, the fixing pin 50 may be formed of, for example, a metal or a plastic material, or may be formed of a material of which only the fixing pin 50 may be selectively removed by an etchant in a case of a later process of separating the fixing pin 50 from the pattern mask 200 and the supporter 300 if necessary. In this case, by using the etchant, only the fixing pin 50 is selectively etched and removed, and the pattern mask 200 and the supporter 300 may be used again.

The supporter 300 may be provided in plural to be separated from each other and the cross-section may be formed of, for example, a circular, a polygonal, or other shape. For example, in an embodiment, the cross-section of the supporter 300 may be formed of a polygon that contacts the pattern mask 200 in a predetermined area when the pressure is applied to the pattern mask 200 to prevent the pattern mask 200 from being damaged by the supporter 300 and to increase a coupling characteristic of the supporter 300 and the pattern mask 200.

When the distance between the mask frame 100 and the pattern mask 200 is increased by the supporter 300, a coupling force between the frame 110 of the mask frame 100 and the coupling part 230 of the pattern mask 200 may be deteriorated and thus the frame 110 of the mask frame 100 should have, for example, a groove 311 to receive the ends of the supporter 300, and a depth of the groove 311 may be the same as the thickness of the supporter 300.

The fixing part P and the fixing pin 50 may be disposed at the frame 110 of the mask frame 100 and the coupling part 230 of the pattern mask 200 to fix the frame 110 and the pattern mask 200.

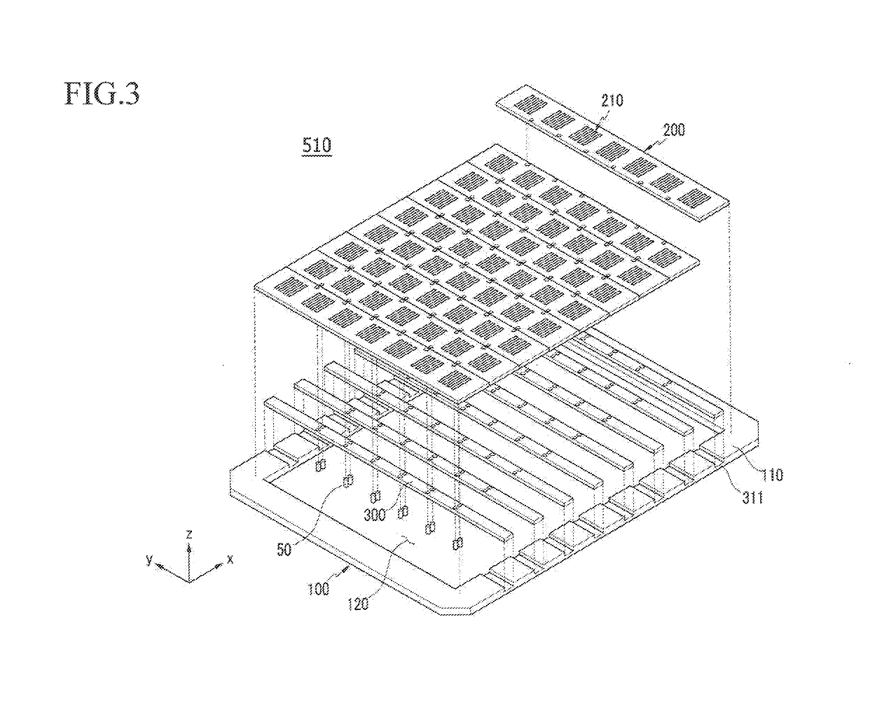

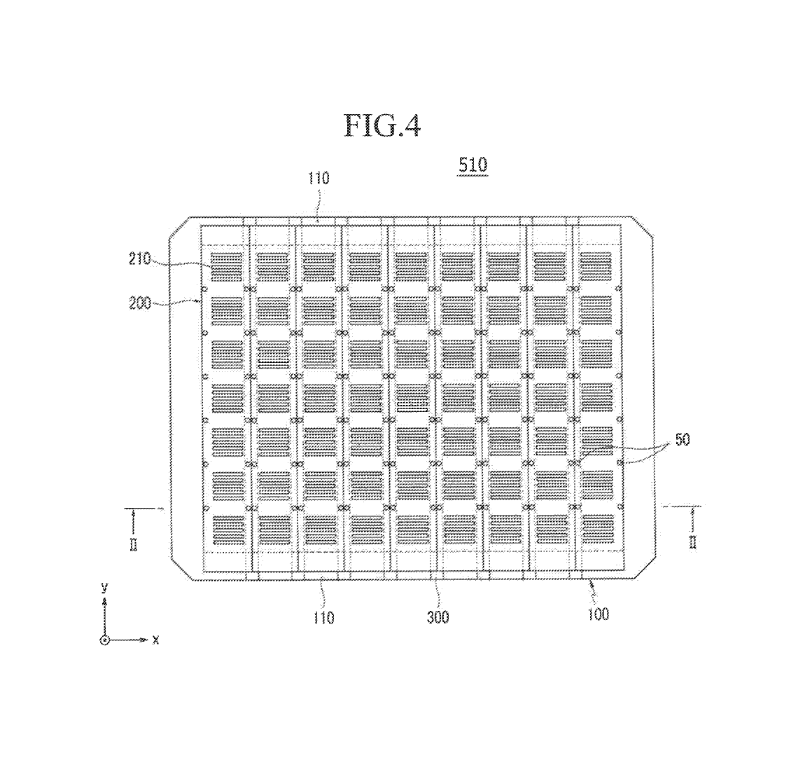

Next, a mask assembly according to an exemplary embodiment of the present invention will be described with reference to FIG. 3 and FIG. 4.

FIG. 3 is a perspective view of a mask assembly according to an exemplary embodiment of the present invention. FIG. 4 is a top plan view of a mask assembly according to an exemplary embodiment of the present invention.

Referring to FIG. 3 and FIG. 4, the mask assembly 510 includes, for example, a mask frame 100 having an opening 120, a pattern mask 200 disposed in parallel with and on the mask frame 100 to be fixed, a supporter 300 positioned between the mask frame 100 and the pattern mask 200, and a fixing pin 50 fixing the pattern mask 200 and the supporter 300.

The mask frame 100 is formed with, for example, a rectangular shape having the opening 120, and the both ends of the pattern mask 200 are fixed to the mask frame 100. At this time, the pattern mask 200 is extended, for example, in the second direction (the Y-axis direction) and is fixed to the mask frame 100 such that the mask frame 100 is formed of the material having the large rigidity to not be deformed by the pressure according to the coupling of the pattern mask 200.

The mask frame 100 includes, for example, parts of the frame 110 facing each other according to the first direction (the X-axis direction) and the second direction (the Y-axis direction) with the opening 120 formed inside the frame 110.

The frame 110 includes, for example, the supporter receiving grooves 311 arranged in the first direction (X-axis direction) to be separated from each other.

The pattern mask 200 is fixed on the frame 110 in, for example, the state that a tensile force is applied according to the length direction. The pattern masks 200 have, for example, a belt shape and are arranged according to one direction such as, for example the first direction (the X-axis direction). The pattern masks 200 may be coupled and fixed in the state that both ends thereof are positioned on the frame 110.

As described above, when forming the mask assembly for the thin film deposition by using the divided pattern masks 200, the pattern mask 200 having the excellent accuracy of the pattern 210 may be selectively used, thereby reducing a shape error of the pattern 210. Also, the uniform tensile force is individually applied according to the length direction of the pattern mask 200 such that the deformation may be prevented from being concentrated at an arbitrary portion of the pattern mask 200.

The pattern 210 of the pattern mask 200 may be formed with, for example, the same shape as an electrode or an emission layer to be formed in a display device.

On the other hand, in the process of aligning a plurality of divided pattern masks 200 on the frame 110, a gap may be generated between the adjacent pattern masks 200 and the deposition material may be passed if the gap remains as it is between the pattern masks 200. The passed deposition material such as, for example, the organic material causes undesired deposition through the gap in the deposition process, thereby generating a defect in the display device. For example, the deposition material that is unnecessarily deposited may short-circuit electrodes formed on the substrate forming a final product or may disturb bonding of the substrate and an encapsulation substrate forming the final product.

In the present exemplary embodiment of the present invention, the supporters 300 are disposed, for example, between the adjacent pattern masks 200 to shield the gap between the pattern masks 200.

A plurality of supporters 300 are provided, spaced according to an arrangement direction of the pattern mask 200, that is, the first direction (the X-axis direction), and arranged under the pattern mask 200. Accordingly, the supporters 300 cross the opening 120 of the mask frame 100 under the plurality of pattern masks 200 and support the pattern masks 200 that are floated on the opening 120.

Also, the supporters 300 are positioned between the pattern masks 200. However, the width of the supporter 300 is narrower than the interval between the patterns 210 of the adjacent pattern masks 200 so as not to cover the pattern 210 in the deposition process. For this, both ends of the supporters 300 are received in a plurality of grooves 311 formed at the frame 110 to be fixed.

On the other hand, the supporter 300 may be formed of the material having high rigidity such as, for example, the same metal as the frame 110. If the frame 110 and the supporter 300 are formed of the same material, they have the same thermal expansion characteristic such that the deformation by the thermal expansion difference may be prevented.

The supporter 300 and the pattern mask 200 respectively have, for example, the fixing part P in which the fixing pin 50 is inserted between the patterns 210 of the pattern mask 200. The fixing parts P may be respectively formed in plural in the supporter 300 and the pattern mask 200, and the fixing parts P of the supporter 300 and the pattern mask 200 are positioned to mutually correspond to each other. Here, for example, in an exemplary embodiment of the present invention, three fixing parts P formed at the supporter 300 and the pattern mask 200 are arranged for each pattern mask 200 in the second direction Y but exemplary embodiments of the present invention are not limited thereto. For example, in an embodiment, there may be less than or more than three fixing parts P.

The fixing pin 50 penetrates the corresponding fixing part P of the supporter 300 and the pattern mask 200 thereby having a function of mutually fixing the supporter 300 and the pattern mask 200. In this case, the fixing pin 50 may have, for example, a cylinder shape, but exemplary embodiments are not limited thereto. For example, in an exemplary embodiment, the fixing pin 50 may have various shapes such as a triangular column shape or a quadrangular column shape, corresponding to the shape of the fixing part P.

Protruded parts of both ends of the fixing pin 50 that are positioned under the supporter 300 and on the pattern mask 200 are pressed by a pressure such that the ends are spread and the pressed cross-section is transformed into, for example, a “T” shape, and thereby the supporter 300 and the pattern mask 200 are fixed to not be mutually separated.

When the upper portion and the lower portion of the fixing pin 50 are pressed by the pressure such that both ends thereof are formed to have the pressed and spread T shape, a gap may be generated by the head height of the pressed and spread fixing pin 50 of the T shape when the pattern mask 200 contacts the substrate. Accordingly, the receiving groove (not shown) receiving the fixing pin 50 of the “T” shape that is formed by the pressed and spread fixing pin 50 may be formed at the circumference of the fixing part P on the pattern mask 200 and under the supporter 300.

Also, according to the process, the receiving groove of the “T” shape of the pressed and spread fixing pin 50 may not be formed. In this case, when performing a deposition process, as a distance between the substrate and the pattern mask 200 is controlled by using the fixing pin 50, a degree of a shadow effect may be artificially controlled.

Also, the fixing pin 50 may be formed of, for example, a metal or a plastic material, or may be formed of a material of which only the fixing pin 50 may be selectively removed by an etchant in a case of a later process of separating the fixing pin 50 from the pattern mask 200 and the supporter 300 if necessary. In this case, by using the etchant, only the fixing pin 50 is selectively etched and removed, and the pattern mask 200 and the supporter 300 may be used again.

For example, in FIG. 3 and FIG. 4, eight supporters 300 having the rectangular cross-sectional are shown but the number of the supporters 300 and the cross-section thereof are not limited thereto.

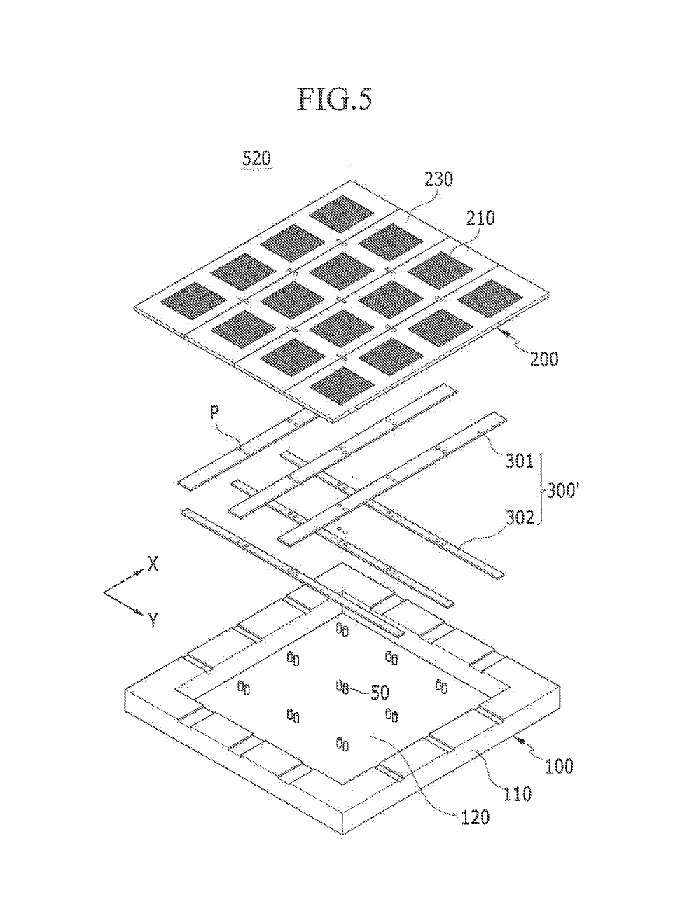

Next, a mask assembly according to an exemplary embodiment of the present invention will be described with reference to FIG. 5.

Referring to FIG. 5, the mask assembly 520 according to the current exemplary embodiment of the present invention includes, for example, a mask frame 100 including an opening 120, and a plurality of pattern masks 200 extended in the length direction of the first direction X and coupled to the mask frame 100, a supporter 300′ crossing the opening 120, and a fixing pin 50 fixing the pattern mask 200 and the supporter 300′. Here, in an exemplary embodiment of the present invention, a plurality of pattern masks 200 are, for example, extended and coupled to the mask frame 100 in the first direction X. However, in an embodiment, a single pattern mask 200 having an area corresponding to the opening 120 may be, for example, extended in one direction among the first direction X and a second direction Y perpendicular to the first direction X, or in all directions.

The mask frame 100 includes, for example, the opening 120 and a frame 110 enclosing the opening 120 and coupled to the pattern mask 200. The frame 110 of the mask frame 100 may be formed of a material having a small change against a compressive force, such as, for example, a metal material having high rigidity so that an end of the pattern mask 200 may be coupled and fixed thereto.

The pattern mask 200 includes, for example, a pattern part 220 in which one or a plurality of patterns 210 are formed to correspond to the opening 120 and a coupling part 230 extended in the first direction X and coupled to the frame 110, and the pattern 210 includes one or a plurality of slits 201. Here, the pattern mask 200 may be a fine metal mask formed of a metal thin film, and may be formed of, for example, one selected from a group including a steel use stainless (SUS), invar, nickel, cobalt, and alloys thereof.

The supporter 300′ is positioned to cross the opening 120 of the mask frame 100 to prevent the pattern mask 200 from being deformed, to shield the gaps between the pattern masks 200. As shown in FIG. 5, when a plurality of pattern masks 200 are coupled to the mask frame 100, the supporters 300 may, for example, cross the opening 120 in the first direction X of the length direction of the pattern mask 200 and the second direction Y perpendicular thereto. To prevent the pattern 210 of the pattern mask 200 from being shielded by the coupling between the supporter 300′ and the pattern mask 200, the supporter 300 is coupled to the pattern mask 200 between the patterns 210 of the pattern mask 200, and thereby a coupling point P between the supporter 300′ and the pattern mask 200 is positioned between the patterns 210.

The supporter 300′ and the pattern mask 200 respectively have, for example, the fixing part P in which the fixing pin 50 is inserted between the patterns 210 of the pattern mask 200 to be fixed. The fixing part P may be respectively formed in plural in the supporter 300′ and the pattern mask 200 and the shape of the fixing pin 50 may be, for example, cylindrical, but exemplary embodiments of the present invention are not limited thereto. For example, in an embodiment, the shape of the fixing pin 50 may be the columnar shape such as the triangular column shape and the quadrangular column shape, corresponding to the shape of the fixing part P.

The positions of the fixing parts P of the supporters 300′ and the pattern masks 200 are formed to mutually correspond to each other. Here, in an exemplary embodiment of the present invention, the fixing parts P are formed, for example, three by three in the first direction and two by two in the second direction Y at the supporter 300′ and the pattern mask 200 but exemplary embodiments are not limited thereto. For example, in an embodiment, the fixing parts P may be formed at less than or more than that.

The fixing pin 50 penetrates the corresponding fixing part P of the supporter 300′ and the pattern mask 200 thereby having a function of mutually fixing the supporter 300′ and the pattern mask 200. In this case, the portions of the fixing pin 50 exposed under the supporter 300′ and on the pattern mask 200 are pressed such that the ends are pressed and spread to be formed of, for example, a “T” shape, and thereby the supporter 300′ and the pattern mask 200 are fixed to not be mutually separated.

The upper portion and the lower portion of the fixing pin 50 are pressed by the pressure such that the both ends thereof are formed with the “T” shape, and a gap may be generated by the head height of the pressed and spread fixing pin 50 of the T shape when the pattern mask 200 contacts the substrate. Accordingly, the receiving groove (not shown) of the “T” shape where the fixing pin 50 is pressed and spread may be formed at the circumference of the fixing part P on the pattern mask 200 and under the supporter 300′.

Also, the receiving groove of the ends of the “T” shape where the fixing pin 50 is pressed and spread may not be formed. In this case, when performing a deposition process, as a distance of the substrate to the pattern mask 200 is controlled by using the fixing pin 50, a degree of a shadow effect may be artificially controlled.

Also, the fixing pin 50 may be formed of, for example, a metal or a plastic material, or may be formed of a material of which only the fixing pin 50 may be selectively removed by an etchant in a case of a later process of separating the fixing pin 50 from the pattern mask 200 and the supporter 300′ if necessary. In this case, by using the etchant, only the fixing pin 50 is selectively etched and removed, and the pattern mask 200 and the supporter 300′ may be used again.

The supporter 300′ includes, for example, a first supporter 301 of the first direction (the X-axis direction) and a second supporter 302 of the second direction (the Y-axis direction) formed to cross each other.

The supporter 300′ may be provided in plural to be separated from each other and the cross-section may be formed of, for example, a circular, a polygonal, or other shape. However, in an embodiment, the cross-section may be formed of, for example, a polygon that contacts the pattern mask 200 in a predetermined area when the pressure is applied to the pattern mask 200, to prevent the pattern mask 200 from being damaged by the supporter 300′ and to increase a coupling characteristic of the supporter 300′ and the pattern mask 200.

When the distance between the mask frame 100 and the pattern mask 200 is increased by the supporter 300′, a coupling force between the frame 110 of the mask frame 100 and the coupling part 230 of the pattern mask 200 may be deteriorated, and thus the frame 110 of the mask frame 100 should have, for example, a groove 311 to receive the ends of the supporter 300′. A depth of the groove 311 may be, for example, the same as the thickness of the supporter 300′.

Also, at the crossing portion of the first supporter 301 and the second supporter 302, the second supporter 302 may include, for example, a receiving groove (not shown) for the first supporter 301 and the depth of the receiving groove may be the same as the thickness of the first supporter 301.

By also disposing the fixing part P and the fixing pin 50 at the frame 110 of the mask frame 100 and the coupling part 230 of the pattern mask 200, the frame 110 and the pattern mask 200 may be fixed.

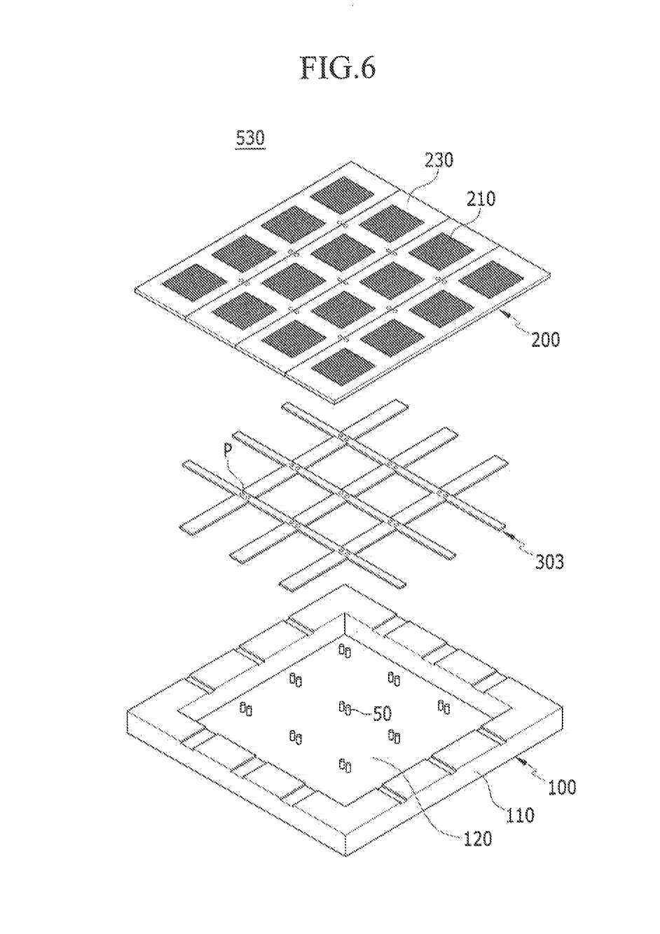

A mask assembly according to an exemplary embodiment of the present invention will be described with reference to FIG. 6.

FIG. 6 is a perspective view of a mask assembly according to an exemplary embodiment of the present invention.

Referring to FIG. 6, the mask assembly according to the current exemplary embodiment of the present invention is the same as the mask assembly shown in FIG. 5, except for a third supporter 303 having a shape of which the first supporter 301 and the second supporter 302 are coupled.

In the mask assembly 530 of the current exemplary embodiment of the present invention, the pattern mask 200 is formed of a plurality of unit masks but exemplary embodiments of the present invention are not limited thereto. Rather, the mask may be formed of a mask of an original shape made of one body as well as the pattern mask 200 of a plurality of unit masks.

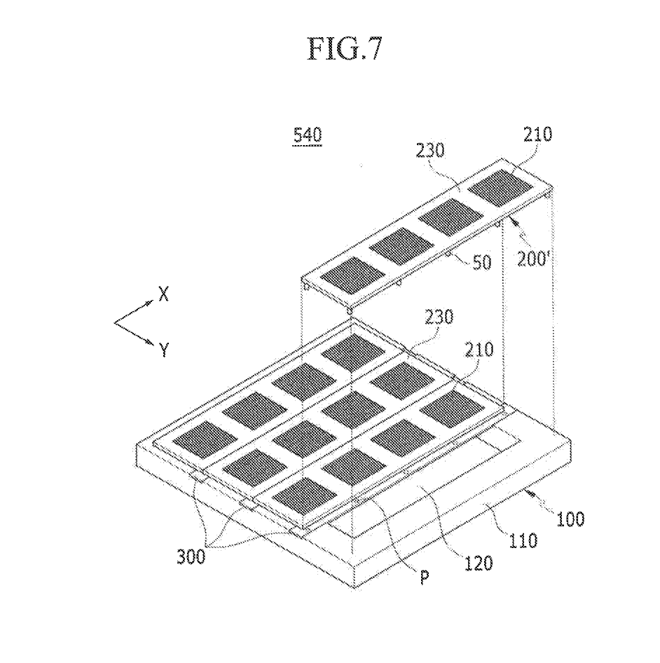

A mask assembly according to an exemplary embodiment of the present invention will be described with reference to FIG. 7.

The mask assembly 540 according to the current exemplary embodiment of the present invention shown in FIG. 7 is substantially the same as the mask assembly shown in FIG. 1 except for the fixing pin 50 such that the repeated description is omitted.

Referring to FIG. 7, the fixing pin 50 may be fixed to the pattern mask 200′ of the portion corresponding to the fixing part P of the supporter 300.

The fixing pin 50 may be fixed to the pattern mask 200 and may be formed of one body along with the pattern mask 200′. In this case, the fixing pin 50 has, for example, a “T” shape such that the underlying supporter 300 is only pressed by the pressure portion.

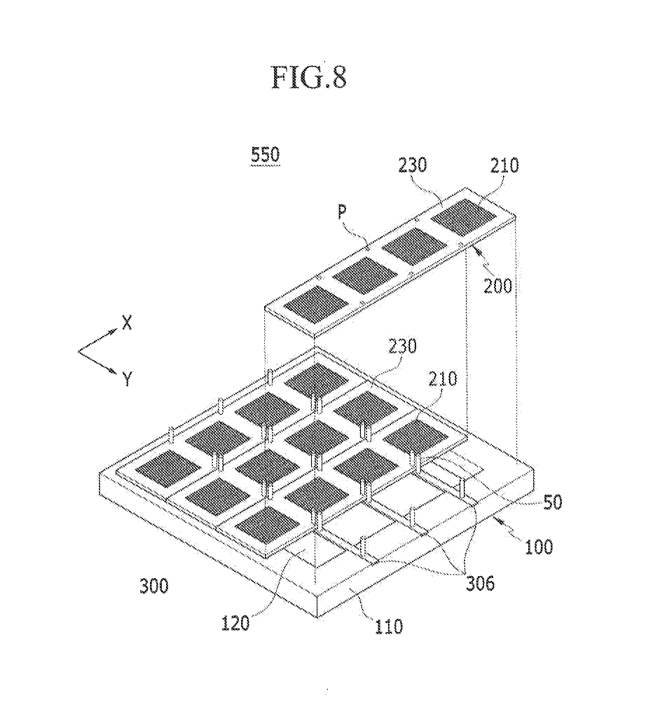

A mask assembly according to an exemplary embodiment of the present invention will be described with reference to FIG. 8.

The mask assembly 550 of the current embodiment of the present invention shown in FIG. 8 is the substantially the same as the mask assembly shown in FIG. 1 except for the fixing pin 50 such that the repeated description is omitted.

Referring to FIG. 8, the fixing pin 50 may be fixed to the supporter 306 of the portion corresponding to the fixing part P of the pattern mask 200.

The fixing pin 50 may be fixed to the supporter 306, and may be formed of one body along with the supporter 306. In this case, the fixing pin 50 has, for example, a “T” shape such that the overlying pattern mask 200 is only pressed by the pressure portion.

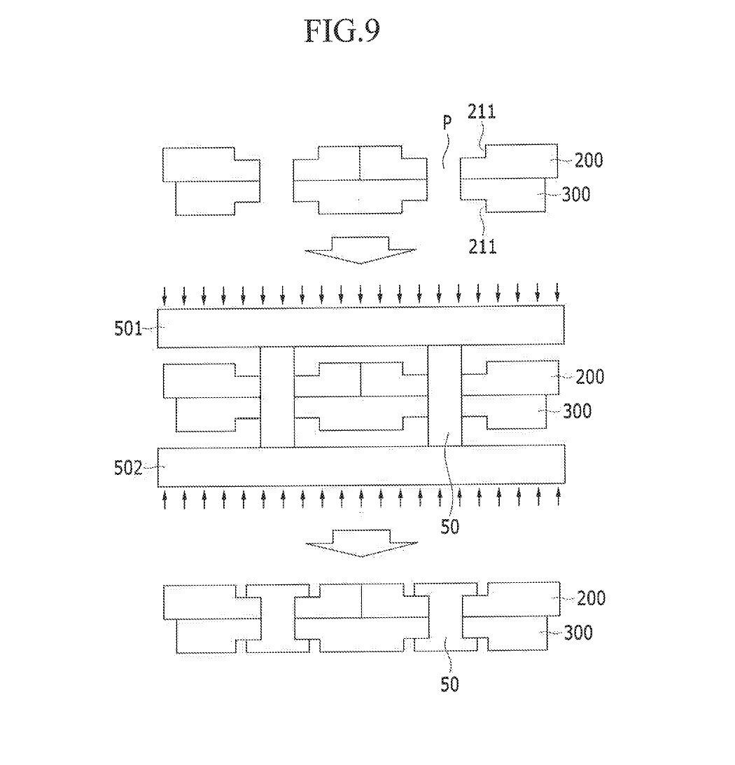

Next, a manufacturing process of a mask assembly according to an exemplary embodiment of the present invention will be described with reference to FIG. 9.

FIG. 9 is a view of a manufacturing process of a mask assembly according to an exemplary embodiment of the present invention.

Referring to FIG. 9, the supporter 300 and the pattern mask 200 having a plurality of corresponding fixing parts P that are coupled, and the fixing pins 50 are respectively inserted into a plurality of fixing parts P.

Next, by applying pressure on 501 and under 502 the fixing pin 50, both ends of the fixing pin 50 that protrude on and under the supporter 300 and the pattern mask 200 are pressed to be spread into the pattern mask 200 and the supporter 300.

The pressed portions of both ends of the fixing pin 50 are received by the fixing pin receiving grooves 211 of the pattern mask 200 and the supporter 300, thereby completing the mask assembly.

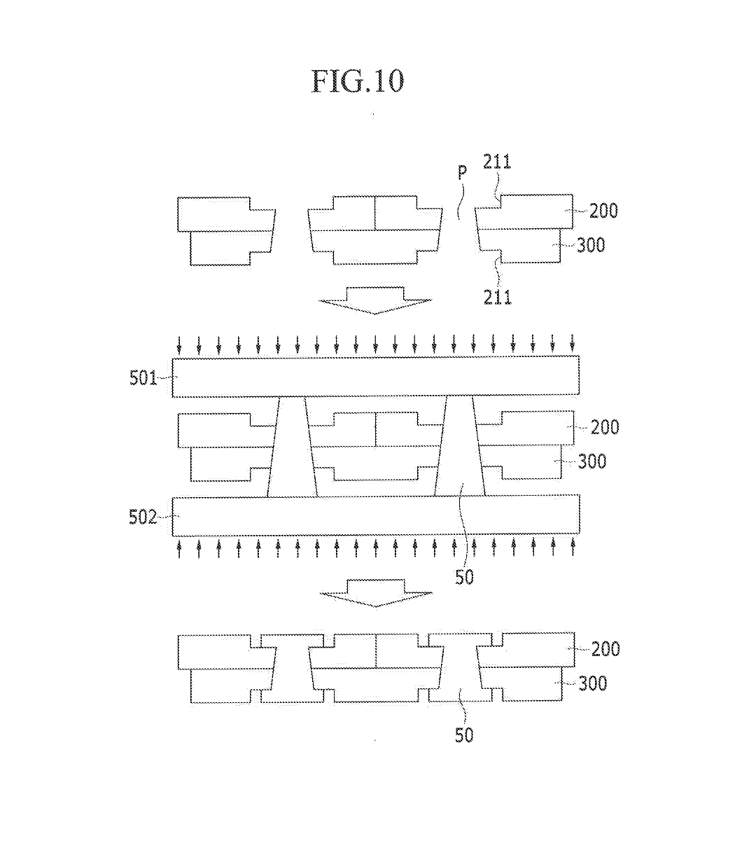

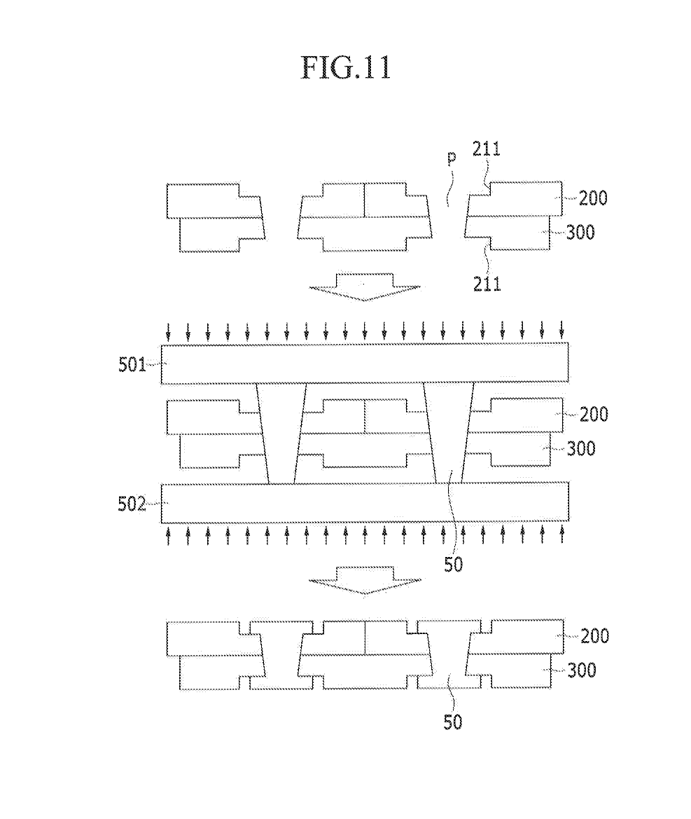

Next, a manufacturing process of a mask assembly according to an exemplary embodiment of the present invention will be described with reference to FIG. 10 and FIG. 11.

Referring to FIG. 10 and FIG. 11, the supporter 300 and the pattern mask 200 having a plurality of corresponding fixing parts P are coupled, and the fixing pins 50 are respectively inserted into a plurality of fixing parts P.

As this time, as shown in FIG. 10, the fixing pin 50 may have a shape of which the upper end is narrow and the lower end is wide, or a shape of which the upper end is wide and the lower end is narrow as shown in FIG. 11.

Next, by applying the pressure on 501 and under 502 the fixing pin 50, both ends of the fixing pin 50 that protrude on and under the supporter 300 and the pattern mask 200 are pressed to be spread into the pattern mask 200 and the supporter 300.

The pressed portions of both ends of the fixing pin 50 are received by the fixing pin receiving grooves 211 of the pattern mask 200 and the supporter 300, thereby completing the mask assembly.

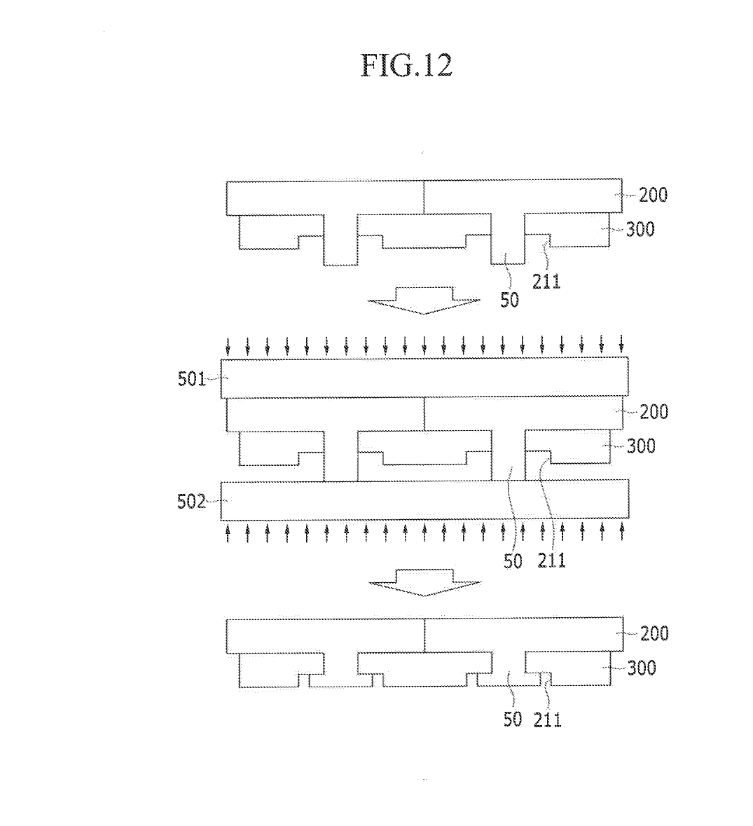

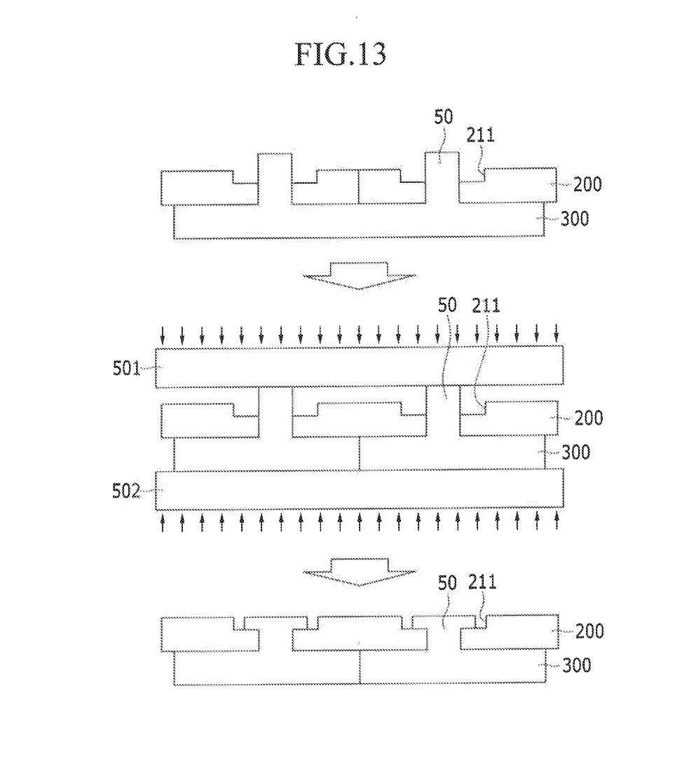

Next, a manufacturing process of a mask assembly according to an exemplary embodiment of the present invention will be described with reference to FIG. 12 and FIG. 13.

Referring to FIG. 12, the supporter 300 having a plurality of corresponding fixing parts P and the pattern mask 200 connected to or integrally formed with the fixing pin 50 are coupled, and the fixing pins 50 connected to the pattern mask 200 are respectively inserted into a plurality of fixing parts P formed at the supporter 300.

In FIG. 12, the fixing pin 50 has the upper end and the lower end having the same area but exemplary embodiments are not limited thereto. For example, alternatively, in an embodiment, the fixing pin 50 may have the shape of which the upper end is narrow and the lower end is wide, or the shape of which the upper end is wide and the lower end is narrow.

Also, the receiving groove 211 is formed at the fixing pin 50 of the supporter 300 but exemplary embodiments are not limited thereto. Alternatively, in an embodiment, the receiving groove 211 may not be formed.

Next, by applying the pressure on 501 the pattern mask 200 and under 502 the fixing pin 50 coupled to the supporter 300 and protruded through the fixing part P of the supporter 300, the ends of the fixing pins 50 protruded under the supporter 300 and coupled to the pattern mask 200 are pressed to be spread into the supporter 200.

The pressed portion of one end of the fixing pin 50 is received by the fixing pin receiving groove 211 of the supporter 300, thereby completing the mask assembly.

Referring to FIG. 13, as opposed to FIG. 12, the pattern mask 200 having a plurality of corresponding fixing parts P and the supporter 300 connected to or integrally formed with the fixing pin 50 are coupled, and the fixing pins 50 connected to or integrally formed with the supporter 300 are respectively inserted into a plurality of fixing parts P formed at the pattern mask 200.

In FIG. 13, the fixing pin 50 has an upper end and a lower end having the same area but exemplary embodiments are not limited thereto. For example, in an exemplary embodiment, the fixing pin 50 may have the shape of which the upper end is narrow and the lower end is wide, or the shape of which the upper end is wide and the lower end is narrow.

The receiving groove 211 is formed at the fixing pin 50 of the pattern mask 200 but exemplary embodiments are not limited thereto. For example, in an embodiment, the receiving groove 211 may not be formed.

Next, by applying the pressure on 501 the supporter 300 and under 502 the fixing pin 50 coupled to the supporter 300 and protruded through the fixing part P of the pattern mask 200, the ends of the fixing pins 50 protruded on the pattern mask 200 and coupled to the supporter 300 are pressed to be spread into the pattern mask 200.

The pressed portion of one end of the fixing pin 50 is received by the fixing pin receiving groove 211 of the pattern mask 200, thereby completing the mask assembly.

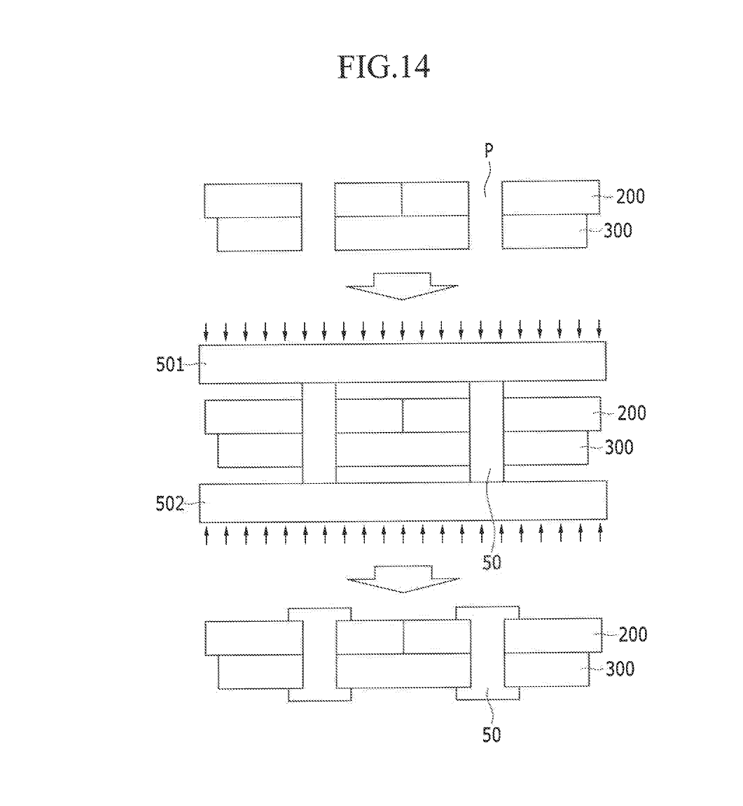

Next, a manufacturing process of a mask assembly according to an exemplary embodiment of the present invention will be described with reference to FIG. 14.

FIG. 14 is a view showing a manufacturing process of a mask assembly of the present invention.

Referring to FIG. 14, the supporter 300 and the pattern mask 200 having a plurality of corresponding fixing parts P are coupled, and the fixing pins 50 are respectively inserted into a plurality of fixing parts P.

Next, by applying the pressure on 501 and under 502 the fixing pin 50, both ends of the fixing pin 50 that protrude on and under the supporter 300 and the pattern mask 200 are pressed to be spread into the pattern mask 200 and the supporter 300.

The pressed portions of both ends of the fixing pin 50 are respectively spread into the surface of the pattern mask 200 and the supporter 300, thereby completing the mask assembly. The height of the pressed portions of both ends of the fixing pin 50 may be controlled by the degree of pressure.

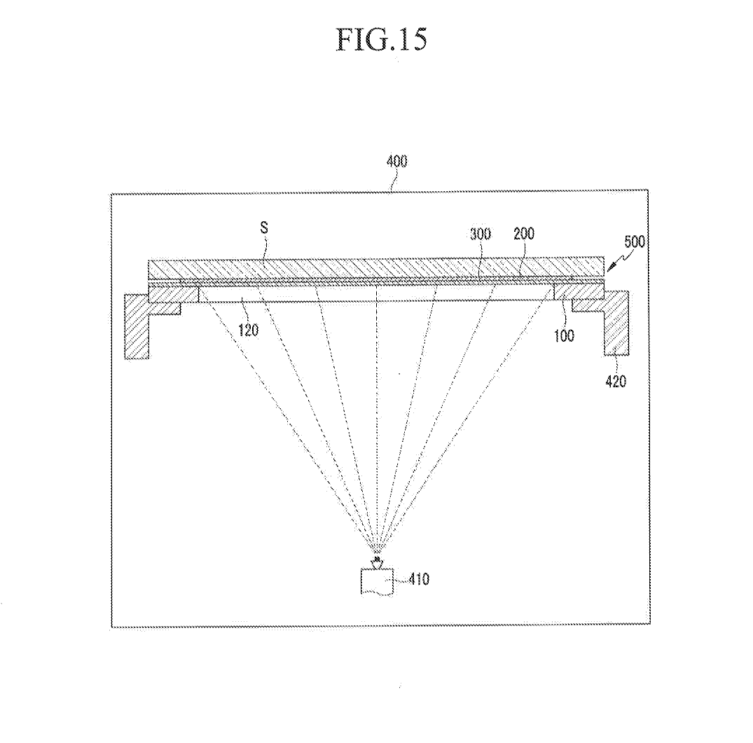

Next, a deposition apparatus for a flat panel display using the mask assembly according to an exemplary embodiment of the present invention will be described with reference to FIG. 15.

Referring to FIG. 15, a deposition apparatus for a flat panel display using the mask assembly according to an exemplary embodiment of the present invention includes, for example, a chamber 400, a deposition source 410 positioned at a lower side of the chamber 400, and a mask assembly 500 positioned on the deposition source 410 and supporting a substrate S. The deposition apparatus for the flat panel display may further include, for example, a separate fixing member 420 to fix the mask assembly 500. Alternatively, in an embodiment, mask assembly 510 of FIG. 3, mask assembly 520 of FIG. 5, mask assembly 530 of FIG. 6, mask assembly of FIG. 7 or the mask assembly 550 of FIG. 8 may be used instead of mask assembly 500 with the deposition apparatus and process illustrated and described in connection with FIG. 15.

Referring to FIG. 15, in a thin film deposition process using the mask assembly according to an exemplary embodiment of the present invention, after fixing the mask assembly 500 to the fixing member 420, the substrate S is positioned on the pattern mask 200 of the mask assembly 500. The substrate S may be positioned to be separated from the pattern mask 200 by a predetermined interval by a separate holder (not shown).

Also, the pattern mask 200 and the substrate S may be positioned to be separated by the predetermined interval by using the fixing pin 50 of the mask assembly 500 without the receiving groove of the fixing pin 50 manufactured by, for example, the process shown in FIG. 14.

Next, if a deposition material is sprayed and evaporated from the deposition source 410 positioned at the lower side of the chamber 400, the deposition material is deposited to have a predetermined pattern on the substrate S by the pattern 210 of the pattern mask 200. When the mask assembly 500 is thermal-expanded by heat inside the chamber 400, to prevent the supporter 300 from being separated or deformed by the thermal expansion characteristic difference between the supporter 300 and the mask frame 100, the supporter 300 may be formed with, for example, the same metal as the mask frame 100.

Due to a weight of the substrate S in the deposition process, if a stress is generated in a direction of the deposition source 410 at the center of the substrate S, the pattern mask 200 supporting the substrate S is coupled to the supporter 300 by the fixing pin 50 such that the stress is dispersed by the supporter 300 supporting the pattern mask 200, and the pattern mask 200 is not deformed.

Also, the pattern mask 200 and the supporter 300 are strongly coupled by the fixing pin 50 coupled to the fixing part P such that the organic material does not penetrate between the pattern mask 200 and the supporter 300 when performing the deposition process, thereby effectively performing the formation of the deposition material.

As described above, according to an exemplary embodiment of the present invention, compared with a method of fixing the supporter and the mask by welding or by forming a protrusion at one side, the deformation of the mask and the supporter by the thermal influence may be removed, the height of the protrusion may be controlled, and the fixing force of the supporter and the mask is strong such that a mask assembly controlling a shadow phenomenon may be provided.

Having described exemplary embodiments of the present invention, it is further noted that it is readily apparent to those of ordinary skill in the art that various modifications may be made without departing from the spirit and scope of the invention which is defined by the metes and bounds of the appended claims.

What is claimed is:

1. A mask assembly comprising:
a mask frame including an opening and a frame enclosing the opening;
a pattern mask including a pattern part in which at least one pattern is disposed thereon and a coupling part coupled to the frame;
a supporter crossing the opening and coupled to the pattern mask; and
a fixing pin coupling the pattern mask and the supporter to each other,
wherein at least one of the pattern mask and the supporter has a fixing part including a plurality of holes, and
wherein the fixing pin is disposed in the fixing part and at least one end of the fixing pin has a “T” shape to fix the pattern mask and the supporter to each other.

2. The mask assembly of claim 1, wherein the pattern includes at least one slit.

3. The mask assembly of claim 2, wherein the pattern mask is made of at least one unit pattern mask.

4. The mask assembly of claim 1, wherein the supporter is formed in plural and are separated from each other.

5. The mask assembly of claim 4, wherein the supporter is disposed in a length direction of the pattern mask.

6. The mask assembly of claim 4, wherein the supporter is disposed in a direction perpendicular to the length direction of the pattern mask.

7. The mask assembly of claim 4, wherein the supporter is disposed in both the direction of the length direction of the pattern mask and the direction perpendicular to the length direction.

8. The mask assembly of claim 1, wherein the frame has a groove configured to receive an end of the supporter therein.

9. The mask assembly of claim 1, wherein at least one of the pattern mask and the supporter has a receiving groove configured to receive the “T” shaped end of the fixing pin therein.

10. The mask assembly of claim 1, wherein the fixing pin is formed of a metal or a plastic material.

11. The mask assembly of claim 10, wherein the fixing pin is formed of a material that is etched by an etchant.

12. The mask assembly of claim 1, wherein the fixing pin is coupled to the pattern mask or the supporter.

13. The mask assembly of claim 12, wherein the fixing pin is united with one of the pattern mask or the supporter.

14. A deposition apparatus for a flat panel display comprising:
a chamber;
a deposition source disposed at a lower side of the chamber; and
a mask assembly disposed on the deposition source and configured to support a substrate,
wherein the mask assembly includes a mask frame including an opening and a frame enclosing the opening, a pattern mask including a pattern part in which at least one pattern is disposed thereon and a coupling part coupled to the frame, a supporter crossing the opening and coupled to the pattern mask, and a fixing pin coupling the pattern mask and the supporter to each other,
wherein at least one of the pattern mask and the supporter has a fixing part including a plurality of holes, and
wherein the fixing pin is disposed in the fixing part and at least one end of the fixing pin has a “T” shape to fix the pattern mask and the supporter to each other.

15. The deposition apparatus of claim 14, wherein the pattern mask is made of at least one unit pattern mask.

16. The deposition apparatus of claim 14, wherein the supporter is formed in plural and are separated from each other.

17. The deposition apparatus of claim 14, wherein at least one of the pattern mask and the supporter has a receiving groove configured to receive the “T” shaped end of the fixing pin therein.

18. The deposition apparatus of claim 14, wherein the fixing pin is formed of a metal or a plastic material.

19. The deposition apparatus of claim 18, wherein the fixing pin is formed of a material that is etched by an etchant.

20. The deposition apparatus of claim 14, wherein the fixing pin is coupled to or is integrally formed with the pattern mask or the supporter.

21. A mask assembly comprising:
a mask frame including an opening and a frame enclosing the opening;
a plurality of pattern masks including a pattern part in which a plurality of patterns are disposed thereon and a coupling part coupled to the frame;
a plurality of supporters crossing the opening of the mask frame underneath the pattern masks and supporting the pattern masks thereon; and
a plurality of fixing pins coupling the pattern masks and the supporters to each other,
wherein the pattern masks and/or the supporters have a fixing part including a plurality of holes, and
wherein the fixing pins are disposed in a corresponding one of the fixing parts and at least one end of the fixing pins have a “T” shape to fix the pattern masks and the supporters to each other, wherein the supporters are fixed to the pattern masks at gaps between the patterns and wherein the supporters have a width which is narrower than a width of the gaps between the patterns of the pattern masks such that the supporters do not shield the patterns of the pattern masks when the supporters and the pattern masks are fixed to each other.

22. The mask assembly of claim 21, wherein the supporters and the frame are formed of a same material as each other having a high rigidity.

23. The mask assembly of claim 21, wherein the frame further comprises a plurality of grooves disposed therein which are configured to receive opposing ends of each of the supporters therein, and wherein a depth of the grooves is substantially the same as a thickness of the supporters.
